(19) United States
(12) Patent Application Publication
(10) Pub. No.: US 2008/0241361 A1
(43) Pub. Date: Oct. 2, 2008

(54) Printed circuit board manufacturing method

(75) Inventors: Ji-Hong Jo, Yeongi-gun (KR); Myung-Sam Kang, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/007,368

(22) Filed: Jan. 9, 2008

(30) Foreign Application Priority Data
Mar. 28, 2007 (KR) 10-2007-0030542

(51) Int. Cl. H05K 3/02

(52) U.S. Cl. 427/98.8; 427/98.9

(57) ABSTRACT

A printed circuit board manufacturing method is disclosed. The printed circuit manufacturing method, which includes forming an adhesive layer on a carrier, adhesiveness of the adhesive layer being changed according to heat; forming a circuit pattern on a surface of the adhesive layer; compressing the carrier into the insulation layer to allow the circuit pattern to face the insulation layer; and separating the carrier from the insulation layer by supplying heat to allow the adhesive to reach a predetermined temperature, can reduce a cost of a transferring process and improve the reliability of products by minimizing the affect on a metal pattern, by using a material having the adhesiveness changed according to the temperature as an adhesive layer.

### CROSS-REFERENCE TO RELATED PATENT APPLICATIONS

This application claims the benefit of Korean Patent Application No. 10-2007-0030542, filed on Mar. 28, 2007, in the Korean Intellectual Property Office, the disclosure of which is incorporated herein in its entirety by reference.

### BACKGROUND OF THE INVENTION

1. Field of the Invention

The present invention relates to a printed circuit board manufacturing method.

2. Background Art

The process of forming a circuit pattern in an insulation layer is the very important core of a printed circuit board manufacturing operation. The manufactured printed circuit board is required to have the circuit pattern with no error in order to completely perform designed functions. The circuit pattern is formed in various ways such as additive, subtractive, inkjet and transfer types.

The transfer type forms a circuit pattern in an additional carrier and compresses the formed circuit pattern into an insulation layer and then removes the carrier, to thereby fill the circuit pattern in the insulation layer.

Conventionally, a metal plate is used for the carrier. The metal pattern is formed by plating the metal plate with a different kind of metal and re-plating the metal plate. At this time, the carrier functions as the subsidiary material that is removed after transfer of the circuit pattern. An etchant is required to be selected considering the reactivity between the metal plate used as the carrier and the different metal plating in the carrier removing process. Further, any error of the carrier removing process may have an affect on the circuit pattern, which results in the problem of reliability.

The metal pattern is formed by performing different metal plating on a single surface of the carrier, the single surface being the metal plate, and re-performing the metal plating on the plated single surface. As such, forming the metal pattern on the single surface may be the loss of the process.

### SUMMARY OF THE INVENTION

The present invention provides a printed circuit board that can reduce a manufacturing cost and improve the reliability of products by changing a separated type between a carrier and a substrate in a method of manufacturing a printed circuit board by using a transfer type.

An aspect of the present invention features a printed circuit board manufacturing method, including forming an adhesive layer on a carrier, adhesiveness of the adhesive layer being changed according to heat; forming a circuit pattern on a surface of the adhesive layer; compressing the carrier into the insulation layer to allow the circuit pattern to face the insulation layer; and separating the carrier from the insulation layer by supplying heat to allow the adhesive layer to reach a predetermined temperature.

The carrier can consist of a material mainly including polyethylene terephthalate (PET), and the adhesive layer can consist of a material including a thermoplastic resin at a rate or more.

In the meantime, the step of forming the circuit pattern can include stacking a metal layer in the adhesive layer; and etching the metal layer selectively. At this time, the step of stacking the metal layer can include providing negative pressure; and thermal-compressing the metal layer and the adhesive layer. Also, the method can further include forming roughness on a surface of the adhesive layer.

Another aspect of the present invention features a printed circuit board, including stacking a first carrier and a second carrier by placing a first adhesive layer that foams if a first temperature is reached; forming a second adhesive layer on each surface of the first carrier and the second carrier, adhesiveness of the second adhesive layer being decreased if a second temperature is reached; forming a circuit pattern on a surface of the second adhesive layer; separating the first carrier and the second carrier from each other by supplying heat to allow the first adhesive layer to reach the first temperature; compressing the first carrier and the second carrier by placing the insulation layer to allow the circuit pattern to face the insulation layer; and separating the first carrier and the second carrier from the insulation layer by supplying heat to allow the second adhesive layer to reach the second temperature.

The first carrier can consist of a material including polyethylene terephthalate (PET), and the first carrier and the second carrier can be stacked in through thermal compression. Also, second adhesive layer can consist of a material including a thermoplastic resin at a rate or more.

The first temperature can be set to be lower than the second temperature. At this time, the first temperature can range between 100 and 160° C.

In the meantime, the step of forming the circuit pattern can include stacking a metal layer in the second adhesive layer; and etching the metal layer selectively. At this time, the step of stacking the metal layer can include providing negative pressure; and thermal-compressing the metal layer and the second adhesive layer. Also, the method can further include forming roughness on a surface of the second adhesive layer.

### BRIEF DESCRIPTION OF THE DRAWINGS

These and other features, aspects and advantages of the present invention will become better understood with regard to the following description, appended claims and accompanying drawings where:

FIG. 1 is a flow chart illustrating a printed circuit board manufacturing method in a first embodiment of the present invention;

FIG. 2A through FIG. 2J illustrate the printed circuit board manufacturing method of FIG. 1;

FIG. 3 is a flow chart illustrating a printed circuit board manufacturing method in a second embodiment of the present invention; and

FIGS. 4A through 4I and FIG. 5A through 5D illustrate the printed circuit board manufacturing method of FIG. 3.

### DESCRIPTION OF THE EMBODIMENTS

Hereinafter, some embodiments of a printed circuit board manufacturing method in accordance with the present invention will be described in detail with reference to the accompanying drawings. Throughout the drawings, similar or corresponding elements are given similar reference numerals. The pertinent overlapped description will be omitted.

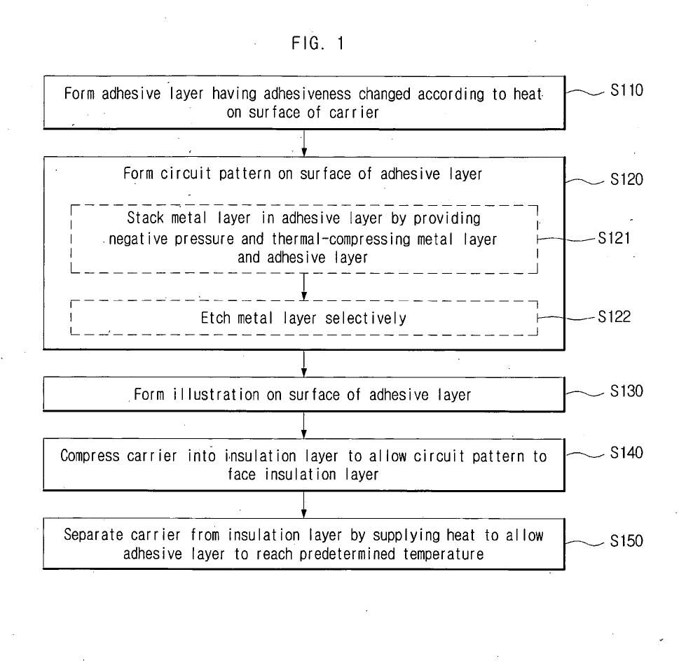

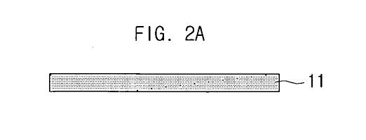

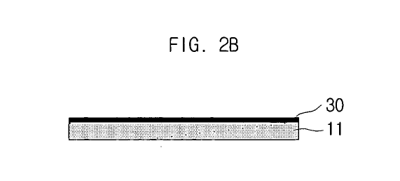

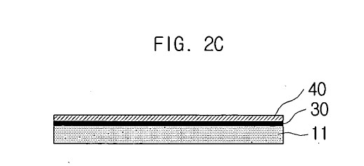

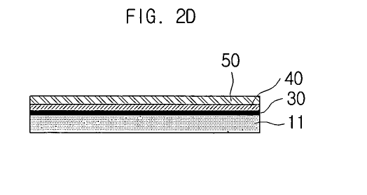

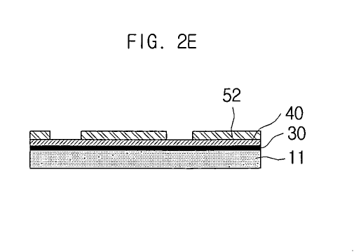

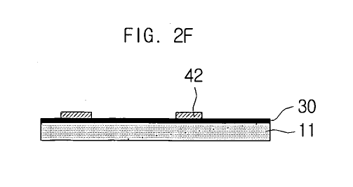

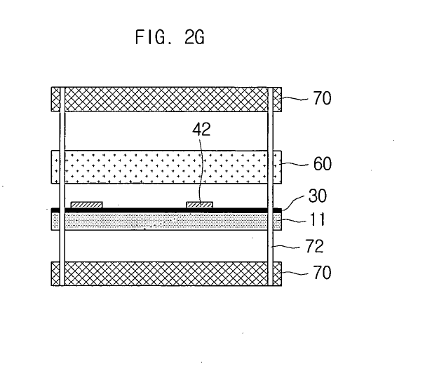

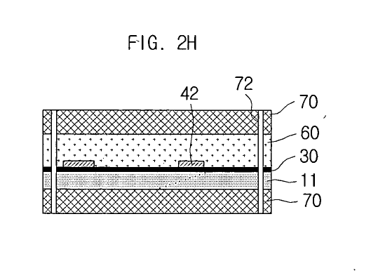

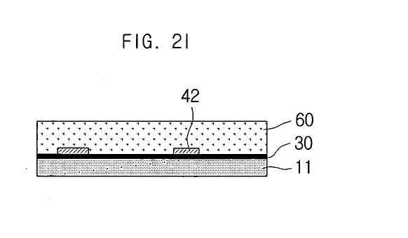

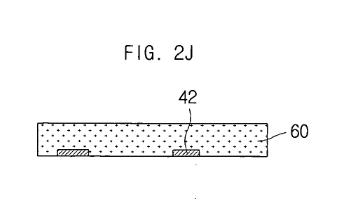

FIG. 1 is a flow chart illustrating a printed circuit board manufacturing method in a first embodiment of the present invention, and FIG. 2A through FIG. 2J illustrate the printed circuit board manufacturing method of FIG. 1. Referring to FIG. 2, a carrier 11, an adhesive layer 30, a metal layer 40, a circuit pattern 42, a dry film 50, an etching resist 52, an insulation layer 60, a compressive plate 70 and an arrangement pin are illustrated.

Firstly, a step represented by S110 can form an adhesive layer 30 having the adhesiveness changed according to heat on a surface of the carrier 11. The carrier 11, which is means for transferring the circuit pattern 42 to the insulation layer 60, can employ smooth polyethylene terephthalate (PET) considering the cost. Of course, any means capable of support the below-described an adhesive layer 30 and circuit pattern 42 can replace the carrier 11.

The adhesive layer 30, which has the adhesiveness changed by heat, can consist of compounds including a thermoplastic resin, for example. The content of thermoplastic resin can be determined according to the type, property and related circumstance of the pertinent thermoplastic resin. For example, the compounds including at least 30% contents of thermoplastic resin can be used. FIG. 2A and FIG. 2B illustrate that the adhesive layer 30 is being formed on a surface of the carrier 11.

Then, a step represented by S120 can form the circuit pattern 42 on a surface of the adhesive layer 30. Later, the circuit pattern 42 can be transferred to the insulation layer 60, to thereby structure the printed circuit board. The circuit pattern 42 can be formed by stacking the metal layer 40 in the adhesive layer 30 in a step represented by S121 (referring to FIG. 2C) and by selectively etching the metal layer 40 in a step represented by S122.

The process of stacking the metal layer 40 in the adhesive layer 30 can be performed by thermal compression in the circumstance in which vacuum or negative pressure close to vacuum is provided, such that the reliability of the circuit pattern 42 can be improved by strengthening the coupling between the metal layer 40 and the adhesive layer 30. Through the thermal compression, the coupling between the adhesive layer 30 and the metal layer 40 can be strengthened. By simultaneously providing negative pressure, the general coupling between the adhesive layer 30 and the metal layer 40 can be evenly performed. This can minimize the possibility that an error is generated in the process of forming the circuit pattern 42 through etching later.

Also, etching the metal layer selectively can be performed by stacking the dry film 50 in the metal layer 40 (refer to FIG. 2D) and forming the etching resister 52 (refer to FIG. 2E) through exposure and development and then supplying an etchant. At this time, acid pretreatment can be performed before stacking the dry film 50 in the metal layer 40. The acid pretreatment can be performed through the method of spraying a nitric acid aqueous solution through a nozzle.

FIG. 2F illustrates that the circuit pattern 42 is formed in the adhesive layer 30 through the forgoing processes.

As such, the circuit pattern 42 can be formed in the adhesive layer 30 stacked in the carrier 11. Then, a surface-treatment, which is the same as the process forming roughness in a surface of adhesive layer 30, can be performed in order to make it easy to separate the insulation layer 60 to which the circuit pattern 42 is transferred later from the adhesive layer 30.

The surface-treatment can be performed by the compulsive plating by discharging silver (Ag), platinum (Pt), gold (Au) and copper (Cu) into a surface of the adhesive layer 30 through sputtering.

Then, a step represented by S140 can compress the carrier 11 into the insulation layer 60 to allow the circuit pattern 42 to face the insulation layer 60. The compressive plate 70 can be used to allow the insulation layer 60 and the carrier 11 to be evenly compressed. The arrangement pin 70 can be used for the arrangement between the insulation layer 60 and the carrier 11. This compression can make it possible for the circuit pattern 42 to be filled in the insulation layer 60. FIG. 2G and FIG. 2, I illustrate the process of compressing the carrier 11 and the insulation layer 60 by using the compressive layer 70.

Then, a step represented by S150 can separate the carrier 11 from the insulation layer 60 by supplying heat to allow the adhesive layer 30 to lead to a predetermined temperature. As described above, the conventional printed circuit board manufacturing method uses the carrier 11 having a metal material and performs the chemical etching to remove the carrier 11.

The embodiment of the present invention can supply heat to allow the adhesiveness of the adhesive layer 30 to reach zero or something close to zero and then removes the carrier 11 and the adhesive layer 30 from the insulation layer 60. This can allow the carrier 11 to be separated easily and have no possibility that an error of the circuit pattern 42 may be generated in the conventional art. FIG. 2F illustrates that the transfer of the circuit pattern 42 is completed after the carrier 11 is separated from the insulation 60.

Through the aforementioned method, the single-layered printed circuit board can be manufactured by forming the circuit pattern 42 in the insulation layer 60, and the multi-layered printed circuit board can be manufactured by a plurality of insulation layers 60 and forming a via for interconnection of each insulation layer 60.

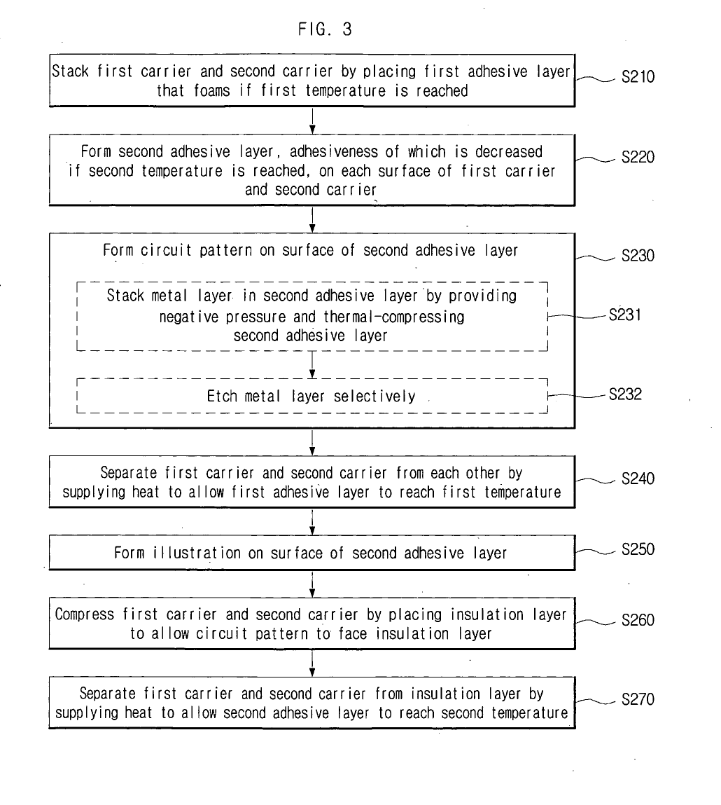

Then, the printed circuit board manufacturing method in accordance with the second embodiment of the present invention will be described with reference to FIGS. 3 through 5D. The printed circuit board manufacturing method in accordance with the embodiment of the present invention transfers the circuit pattern to both surface of an insulation layer unlike the first embodiment of the present invention.

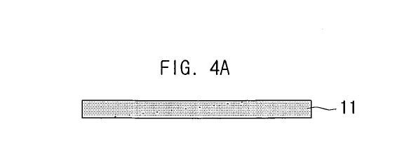

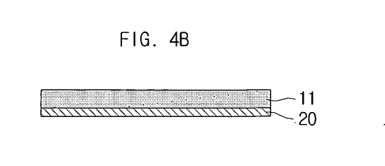

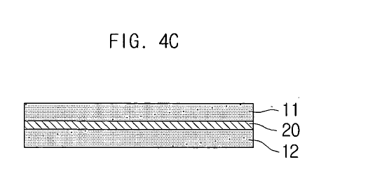

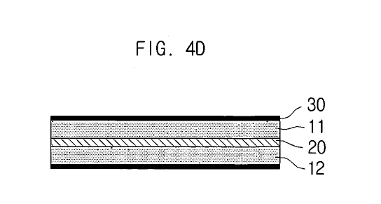

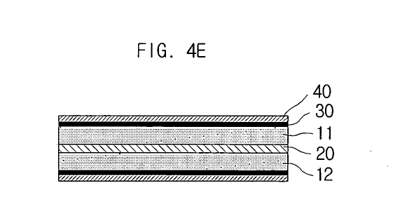

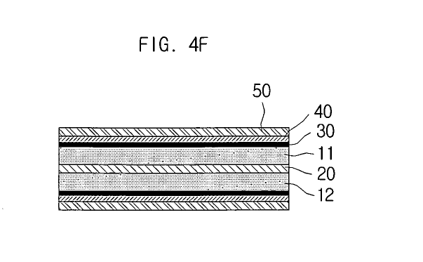

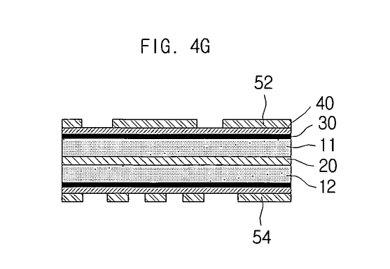

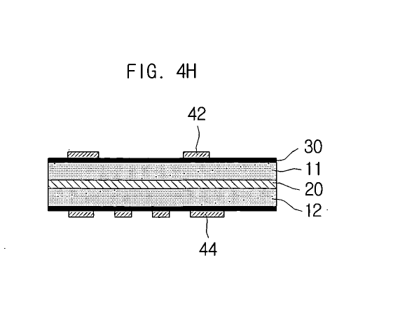

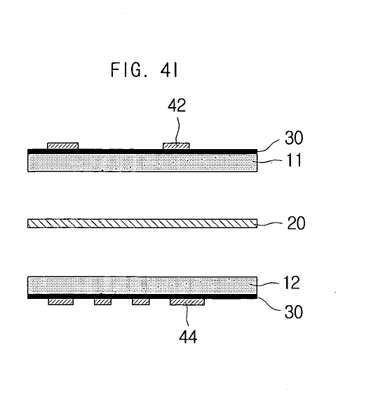

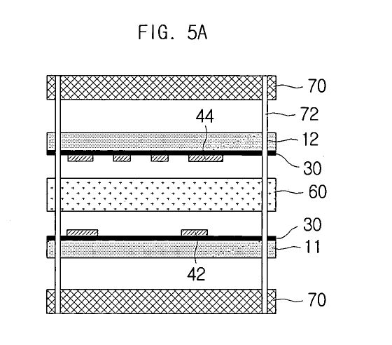

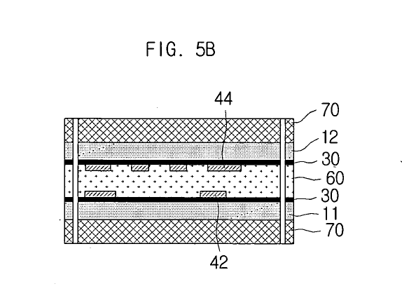

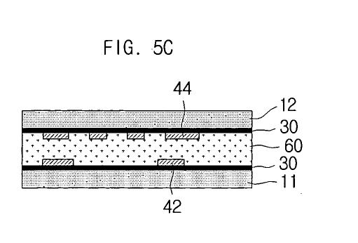

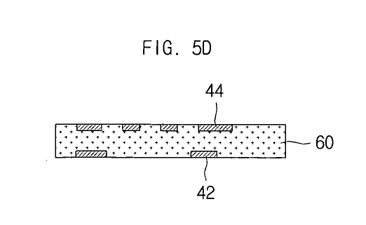

FIG. 3 is a flow chart illustrating a printed circuit board manufacturing method in a second embodiment of the present invention, and FIGS. 4A through 4I and FIGS. 5A through 5D illustrate the printed circuit board manufacturing method of FIG. 3. Referring to FIGS. 4A through 5D, a first carrier 11, a second carrier 12, a first adhesive layer 20, a second adhesive layer 30, a metal layer 40, circuit patterns 42 and 44, a dry film 50, etching resists 52 and 54, an insulation layer 60, a compressive plate 70 and arrangement pin 72.

Firstly, a step represented by S210 can place the first adhesive layer 20 that foams if a first temperature is reached and stack the first carrier 11 and the second carrier 12 in order to prepare two carriers for transferring the circuit patterns 42 and 44 to both surfaces of the insulation layer 60 later at a time. Like the first embodiment, the first and second carriers can employ smooth polyethylene terephthalate (PET).

In the meantime, the first carrier 11 and the second carrier 12 can be stacked in through thermal compression. Considering that the first adhesive layer 20 is placed between the first carrier 11 and the second carrier 12, the thermal compression can be used in order to allow the first carrier 11 and the second carrier 12 to be strongly coupled to each other. Accordingly, when performing a next process applied to the first and second carriers 11 and 12 together, higher reliability can be acquired. This process that the first carrier 11 and the second carrier 12 are stacked in is illustrated in FIGS. 4A through 4C.

Then, a step represented by S220 can form the second adhesive layer 30 in the first carrier 11 and the second carrier 12, respectively. If the second adhesive layer 30 reaches a second temperature, the adhesiveness is decreased. The second adhesive layer 30 in accordance with the second embodiment of the present invention can correspond to the adhesive layer 30 (refers to FIG. 2) in accordance with the first embodiment of the present invention. For example, the adhesive layer 30 can consist of compounds including a thermoplastic resin. The content of thermoplastic resin can be determined according to the type, property and related circumstance of the pertinent thermoplastic resin. For example, the compounds including at least 30% contents of thermoplastic resin can be used. FIG. 4D illustrates that the second adhesive layer 30 is formed in each surface of the first carrier 11 and the second carrier 12.

Then, a step represented by S230, which corresponds to the step represented by S120, can form the circuit patterns 42 and 44 in the surface of the second adhesive layer 30. In particular, like the first embodiment, a step represented by 231 (refers to FIG. 4E) stacks the metal layer 40 in the second adhesive layer 30. Then, a step represented by S232 selectively etches the metal layer 40 to form the circuit patterns 42 and 44 as described above, the process of stacking the metal layer 40 in the second adhesive layer 30 can be performed by thermal compression in the circumstance in which vacuum or negative pressure close to vacuum is provided, such that the reliability of the circuit patterns 42 and 44 can be improved by strengthening the coupling between the metal layer 40 and the second adhesive layer 30.

FIG. 4F through FIG. 4H illustrate the process of etching the metal layer 40 and forming the circuit patterns 42 and 44 by stacking the dry film 50 in the metal layer 40 (refer to FIG. 4F) and forming the etching resister 52 (refer to FIG. 2E) through exposure and development and then supplying an etchant. Like the first embodiment, acid pretreatment can be also performed before stacking the dry film 50 in the metal layer 40.

Then, a step represented by S240 can separate the first carrier 11 and the second carrier 12 from each other by supplying heat to allow the adhesive layer 30 to lead to a predetermined temperature in order to transfer the circuit patterns 42 and 44 to both surfaces of the insulation layer 60 together.

If the first adhesive layer 20 reaches a first temperature, the first adhesive layer 20 may generate a foam. The generated foam may cause the adhesiveness to be lowered, to thereby make it easy to separate the first carrier 11 and the second carrier 12.

The first temperature can be determined considering all processes of manufacturing the printed circuit board, for example, between 100 and 160° C.

In the meantime, if the first temperature generating the foam in the adhesive layer 20 is the same as or higher than the second temperature decreasing the adhesiveness of the second adhesive layer 30, there may occur the problem that the coupling between the circuit patterns 42 and 44 and the second adhesive layer 30 is not strongly maintained. It may be difficult that the only adhesiveness between the first carrier 11 and the second carrier 12 is lowered in the state where the adhesiveness between the second adhesive layer 30 and the circuit patterns 42 and 44 is maintained.

Accordingly, it can be preferable that the first temperature generating the foam in the adhesive layer 20 is smaller than the second temperature decreasing the adhesiveness of the second adhesive layer 30. In this case, the adhesiveness between the first carrier 11 and the second carrier 12 can be lowered without having an affect on the adhesiveness between the second adhesive layer 30 and the circuit patterns 42 and 44.

A step represented by S250 can separate the first carrier 11 and the second carrier 12 and then perform a surface-treatment, which is the same as the process forming roughness in a surface of adhesive layer 30 in order to make it easy to separate the insulation layer 60 to which the circuit patterns 42 and 44 are transferred later from the adhesive layer 30. The surface-treatment can be performed by the compulsive plating by discharging silver (Ag), platinum (Pt), gold (Au) and copper (Cu) into a surface of the adhesive layer 30 through sputtering.

Then, a step represented by S260 can compress the first carrier 11 and the second carrier 12 by placing the insulation layer 60 to allow the circuit patterns 42 and 44 to face the insulation layer 60. For example, the circuit patterns 42 and 44 can transferred to both surfaces of the insulation layer 60 together. The compressive plate 70 can be used to allow the insulation layer 60 and the first carrier 11 and the second carrier 12 to be evenly compressed. The arrangement pin 70 can be used for the arrangement between the insulation layer 60 and the first carrier 11 and the second carrier 12. This compression can make it possible for the circuit patterns 42 and 44 to be filled in the insulation layer 60. FIG. 5A and FIG. 5C illustrate the process of compressing the carriers 11 and 12 and the insulation layer 60 by using the compressive layer 70.

In addition, a step represented by S270 can supply heat to the second adhesive layer 30 to lead to a second temperature so as to separate the first carrier 11 and the second carrier 12 from the insulation layer 60. As described through the first embodiment, the method supplying heat to allow the adhesiveness of the adhesive layer 30 to reach zero or something close to zero and then removing the carriers 11 and 12 and the adhesive layer 30 from the insulation layer 60 can be used. This can allow the carriers 11 and 12 to be separated easily and have no possibility that an error of the circuit patterns 42 and 44 may be generated in the conventional art. FIG. 5D illustrates that the transfer of the circuit patterns 42 and 44 is completed after the carriers 11 and 12 are separated from the insulation layer 60.

Through the aforementioned method, the single-layered printed circuit board can be manufactured by forming the circuit pattern in the insulation layer, and the multi-layered printed circuit board can be manufactured by a plurality of insulation layers and forming a via for interconnection of each insulation layer.

Hitherto, the method of manufacturing the printed circuit board in accordance with various embodiments of the present invention has been described. A lot of other embodiments can described within the principles and spirit of the invention, the scope of which shall be defined by the appended claims.

What is claimed is:

1. A printed circuit board manufacturing method, comprising:
forming an adhesive layer on a carrier, adhesiveness of the adhesive layer being changed according to heat;
forming a circuit pattern on a surface of the adhesive layer;
compressing the carrier into the insulation layer to allow the circuit pattern to face the insulation layer; and
separating the carrier from the insulation layer by supplying heat to allow the adhesive layer to reach a predetermined temperature.

2. The method of claim 1, wherein the carrier consists of a material including polyethylene terephthalate (PET).

3. The method of claim 1, wherein the adhesive layer consists of a material including a thermoplastic resin.

4. The method of claim 1, wherein the step of forming the circuit pattern comprises
stacking a metal layer in the adhesive layer; and
etching the metal layer selectively.

5. The method of claim 4, wherein the step of stacking the metal layer comprises
providing negative pressure; and
thermal-compressing the metal layer and the adhesive layer.

6. The method of claim 1, further comprising forming roughness on a surface of the adhesive layer.

7. A printed circuit board manufacturing method, comprising:
stacking a first carrier and a second carrier by placing a first adhesive layer that foams if a first temperature is reached;
forming a second adhesive layer on each surface of the first carrier and the second carrier, adhesiveness of the second adhesive layer being decreased if a second temperature is reached;
forming a circuit pattern on a surface of the second adhesive layer;
separating the first carrier and the second carrier from each other by supplying heat to allow the first adhesive layer to reach the first temperature;
compressing the first carrier and the second carrier by placing the insulation layer to allow the circuit pattern to face the insulation layer; and
separating the first carrier and the second carrier from the insulation layer by supplying heat to allow the second adhesive layer to reach the second temperature.

8. The method of claim 7, wherein the first carrier consists of a material including polyethylene terephthalate (PET).

9. The method of claim 7, wherein the first carrier and the second carrier are stacked in through thermal compression.

10. The method of claim 7, wherein the second adhesive layer consists of a material including a thermoplastic resin.

11. The method of claim 7, wherein the first temperature is lower than the second temperature.

12. The method of claim 7, wherein the step of forming the circuit pattern comprises
stacking a metal layer in the second adhesive layer; and
etching the metal layer selectively.

13. The method of claim 12, wherein the step of stacking the metal layer comprises
providing negative pressure; and
thermal-compressing the metal layer and the second adhesive layer.

14. The method of claim 7, further comprising forming roughness on a surface of the second adhesive layer.
